(19) United States
(12) Patent Application Publication
(10) Pub. No.: US 2006/0246706 A1
(43) Pub. Date: Nov. 2, 2006

(54) Conductive bump structure for semiconductor device and fabrication method thereof

(75) Inventors: Chun Chi Ke, Taichung (TW); Chien-Ping Huang, Taichung (TW); Don-Son Jiung, Taichung (TW); Yu-Po Wang, Taichung (TW)

Correspondence Address: BACON & THOMAS, PLLC, 625 SLATERS LANE, FOURTH FLOOR, ALEXANDRIA, VA, 22314, US

(73) Assignee: SILICONWARE PRECISION INDUSTRIES CO., LTD., Taichung (TW)

(21) Appl. No.: 11/401,882

(22) Filed: Apr. 12, 2006

(30) Foreign Application Priority Data
Apr. 12, 2005 (TW) 094111456

(51) Int. Cl. H01L 21/44

(52) U.S. Cl. 438/613

(57) ABSTRACT

A conductive bump structure for a semiconductor device and a method for fabricating the same are provided. A metal bump is formed on an under bump metallurgy (UBM) structure electrically connected to and formed on a connection pad of the semiconductor device, wherein the metal bump is sized smaller than the UBM structure. Subsequently, a solder bump is mounted on the UBM structure and encapsulates the metal bump, so as to increase the bonding area and simultaneously allow the solder bump to be sufficiently wetted on the UBM structure to enhance bonding stress of the solder bump.

### FIELD OF THE INVENTION

The present invention relates to conductive bump structures for semiconductor devices and methods for fabricating the same, and more particularly, to a solder bump structure formed on a semiconductor device and a method for fabricating the same.

### BACKGROUND OF THE INVENTION

Along with evolution of semiconductor fabrication technology and boosting circuit functions of chips, demands for various portable products in the fields of communication, network and computer technology have increased dramatically. In order to meet ever-increasing demands for miniaturized electronic products, advanced semiconductor packaging techniques such as ball grid array (BGA), flip chip, chip size package (CSP) and wafer level chip scale package (WLCSP) are required and become more popular as such packaging techniques are capable of reducing size and area of integrated circuit while forming a high-density semiconductor package with multi-pins.

For instance, one of the main differences between a flip-chip semiconductor packaging technique and a conventional wire bond packaging technique is that a semiconductor chip of a flip-chip semiconductor package is mounted on a substrate with its active surface facing downward, allowing the chip to be soldered by a solder bump formed on the active face, such that the chip is electrically connected to the substrate. Furthermore, as the flip-chip semiconductor packaging technique allows the semiconductor chip to be electrically connected to the substrate without the use of bonding wires that require more space, the whole package structure has therefore become lighter, slimmer and smaller.

Referring to FIG. 1, when soldering a solder bump 150 to a semiconductor chip 100, an under bump metallurgy (UBM) structure 130 is formed on a connection pad 110 of the semiconductor chip 100 first. The UBM structure 130 comprises an adhesion layer 130a formed on the connection pad 110, wherein the adhesion layer 130a is made of aluminum; a barrier layer 130b for preventing diffusion, wherein the barrier layer 130b is made of nickel-vanadium alloy; and a wettable layer 130c for being coupled to the solder bump 150, wherein the wettable layer 130c is made of copper. Subsequently, the UBM structure 130 is coupled to the solder bump 150, so as to serve as a diffusion barrier and provide adequate adhesion between the solder bumps 150 and the connection pads 110 of the semiconductor chip 100. Then a solder material is applied to UBM structure, and a reflow process is performed on the solder material to form a solder bump. Generally, an UBM structure may be made by sputtering, evaporation or plating etc.

FIGS. 2A to 2E are schematic cross-sectional views showing procedural steps of a method for fabricating flip-chip solder bumps on a semiconductor wafer in prior art. As shown in FIG. 2A, a semiconductor wafer 100 with a plurality of connection pads 110 formed thereof is provided first, then, a passivation layer 120 is formed over the semiconductor wafer 100 without covering the connection pads 110, and an UBM structure 130 is formed on each of the connection pads 110 by sputtering or plating. As shown in FIG. 2B, a dry film 140 is formed on the passivation layer 120, and a plurality of openings 141 are formed in the dry film 140 by exposing and developing, such that the UBM structure 130 is exposed. As shown in FIG. 2C, a printing process of the solder material is performed. During the printing process, the solder material such as a tin-lead alloy (Sn/Pb), is filled into the openings 141 via the dry film 140 by the use of a scraper 145 to form a plurality of solder bumps 150. Further, as shown in FIG. 2D, a first reflow process is performed to solder the solder material to the UBM structure 130, then, the dry film 140 is removed and a second reflow process is performed to reshape the solder bumps 150 into balls (FIG. 2E).

There are many patents related to UBM structures and solder bump processes such as U.S. Pat. No. 5,773,359, No. 5,137,845 and No. 5,904,859. Nevertheless, most of the commonly-known structures of solder bumps are not fabricated well in prior art. In other words, when a semiconductor chip is electrically connected to an external electronic component via a solder bump, the solder bump would be cracked easily. The reason is that the solder bump has to carry most of stress and convert the stress to strain capacity in order to absorb the force. Further, the problems relating to bump cracking may become worse, if a fragile lead-free solder bump is used due to environment concerns. In addition to bump cracking, the UBM structure is also expected to be damaged in a similar circumstance.

In order to solve the foregoing problems relating to solder bumps with insufficient strength and hardness, U.S. Pat. No. 5,698,465 and No. 6,548,393 disclose a structure of which a copper pillar or conductive trace is mounted inside a solder bump to increase bonding area of the solder bump and to provide higher bonding strength for the solder bump.

Further, if a solder bump is to be integrated with a copper pillar, the copper pillar has to be formed by a plating process, which is extremely time-consuming and cost inefficient. As the fabrication process of copper pillar is very complicated and expensive, method as such is not practical for fabricating the solder bump in the field. Referring to FIG. 3, U.S. Pat. No. 5,633,204 discloses having a gold wire held by a capillary of a wire bonder above an electrode connection pad 300 (such as an aluminum pad) of a chip 30 and forming a tip of a gold wire into a ball, and subsequently pressing the ball to the electrode connection pad 300 by the use of the capillary to form a gold bump 34. Then, a solder bump 35 is formed on the gold bump 34, without being contacted by the electrode connection pad 300. Accordingly, the chip is electrically connected to an external apparatus by the bump structure consisting of the gold bump 34 and the solder bump 35.

Further, as the gold bump is soldered directly on the aluminum pad in the foregoing structure, it is easy to form an fragile intermetallic compound (IMC) such as Au₄Al, between gold (Au) and aluminum (Al). As a result, cracks could occur between the gold bump and the aluminum pad and severely deteriorate reliability of the fabrication process. Furthermore, as the solder bump only attaches to the gold bump, the solder bump cannot be efficiently wetted to the aluminum pad. Accordingly, when a chip is flip-chip soldered to an external apparatus by the solder bump to form a solder joint, all external stress is applied to the gold bump. Furthermore, under high temperature storage or long duration period, IMC formed between the gold bump and the aluminum pad could easily have voids formed therein, thereby causing the flip-chip structure to form cracks around the voids and leading to a shorten lifetime of the solder joint.

FIGS. 4A and 4E are schematic cross-sectional views showing a fabrication method of another bump structure disclosed in U.S. Pat. No. 6,864,168. First, as shown in FIG. 4A, a wafer 40 is provided. A surface of the wafer 40 is formed with a connection pad 400 and covered by a passivation layer 41 exposing the connection pad 400, wherein a metal layer 420 is formed on the surface of the passivation layer 41 and exposed connection pad 400. As shown in FIGS. 4B and 4C, a solder wire 441 is held by a capillary 46 of a wire bonder and a ball 442 is formed at one tip of the solder wire 441. Then the ball 442 is pressed against the metal layer 420 at a position corresponding to the connection pad 400 on the wafer 40. As shown in FIG. 4D, the capillary 46 is removed and the solder wire 441 is detached such that a bonding mass 44 is formed on the metal layer 420 at a position corresponding to the connection pad 400. The bonding mass 44 serves as an etching resist layer during removal of the metal layer 420. After the metal layer 420 is removed, an UBM structure 42 is formed between the bonding mass 44 and the connection pad 400. Subsequently, as shown in FIG. 4E, a solder material is formed by printing and a reflow process is performed to form the solder material into a solder bump 450.

In view of the foregoing fabricating processes, as the UBM structure is formed by using the bonding mass as etching resist layer in an etching process, the size of the bonding mass is larger than the UBM structure. As a result, it is not possible for the solder bump formed subsequently to have wetting junction with the UBM structure, thereby leading to lack of efficient junction stress. In addition, as the location and size of the UBM structure are decided by the location and size of the bonding mass formed on the wafer by pressing process conducted via the wire bonder, precision error of pressing location easily leads to a deviation of the locations of the bonding mass and the UBM structure, and as a result, the subsequent solder bump could not be formed correctly on a predefined location, which seriously affects reliability of subsequent electrical connection between chip and external apparatus. Furthermore, since the size of the UBM structure is depended on the capability and performance of the wire bonder in forming a ball, a variation in the ball size often happens and therefore results in a variation in the size of the UBM structure, which affects push and pull stress of the solder bump and thus affects reliability of products. In addition, as the size of the UBM structure varies with the size of the bonding mass, if the size of the UBM structure is smaller than the connection pad, the efficient junction area of the solder bump would become seriously insufficient, thereby affecting the push and pull stress of the solder bump severely.

Moreover, referring to the foregoing fabrication processes, when forming the solder material by a printing method, the chip is first covered with a dry film and then the dry film is formed with an opening corresponding to the bonding mass by exposing and developing, so as to allow the solder material to be deposited in the opening by printing and a reflow process to be performed subsequently. However, in practical implementation for covering the dry film, it is difficult to paste the dry film over the wafer well and smoothly due to the protrusion of the bonding mass, thereby forming the holes around the bonding mass easily. Therefore, a developing fluid may enter into or permeate through the dry film, and cause a loosened dry film, which consequently aborts the subsequent printing process of the solder material.

### SUMMARY OF THE INVENTION

In light of the above prior-art drawbacks, a primary objective of the present invention is to provide a conductive bump structure for a semiconductor device and a method for fabricating the same, which can increase bonding strength between the semiconductor device and external components.

Another objective of the present invention is to provide a conductive bump structure for a semiconductor device and a method for fabricating the same, which can avoid problems such as to the formation of IMC between gold and aluminum when mounting a gold bump directly on an aluminum pad for forming a solder bump, or the crack occurrence on the solder bump mounted on the gold bump due to the formation of IMC.

Still another objective of the present invention is to provide a conductive bump structure for a semiconductor device and a method for fabricating the same, which can make a solder material be efficiently wetted on an under bump metallurgy (UBM) structure of the semiconductor device for strengthening the solder bump stress.

A further objective of the present invention is to provide a conductive bump structure for a semiconductor device and a method for fabricating the same, which can prolong lifetime of the solder bump used for electrical connecting the semiconductor device to external components.

Yet another objective of the present invention is to provide a conductive bump structure for a semiconductor device and a method for fabricating the same, which can avoid increase in cost of production and process complexity due to the use of a copper pillar in a solder bump.

A further objective of the present invention is to provide a conductive bump structure for a semiconductor device and a method for fabricating the same, which can provide an UBM structure that is sized larger than a bonding mass and a connection pad of the semiconductor device so that the stress of a solder bump subsequently formed on the connection pad would not be limited.

A further objective of the present invention is to provide a conductive bump structure for a semiconductor device and a method for fabricating the same, which allow the stress and location of a conductive bump structure not to be affected by unfavorable or adverse influences on the precision of a bonding mass and a wire bonder.

In accordance with the foregoing and other objectives, the present invention proposes a method for fabricating a conductive bump structure for a semiconductor device, comprising the steps of: providing a semiconductor device with a connection pad formed thereon and forming an under bump metallurgy (UBM) structure on the connection pad of the semiconductor device, wherein the UBM structure is electrically connected to the connection pad; applying a resist layer on the semiconductor device, and forming an opening in the resist layer for exposing the UBM structure via the opening; forming at least one metal bump on the UBM structure, wherein the metal bump is sized smaller than the UBM structure; forming a solder material in the opening by printing, and performing a first reflow process for fixing the solder material to the metal bump and the UBM structure; and removing the resist layer, and performing a second reflow process for forming a solder bump on the UBM structure, wherein the solder bump completely encapsulates the metal bump.

The semiconductor device may be used in a substrate for semiconductor package or a tape carrier such as a tape carrier package (TCP). The semiconductor device may also be used in a printed circuit board for assembling electrical components in second phase. Furthermore, the semiconductor device may be used in a wafer/chip integrated circuit structure that may subsequently be used as a flip-chip semiconductor wafer/chip or wafer level chip scale package (WLCSP). The connection pad may be redistributed through a redistribution layer (RDL). The metal bump may be a gold bump or a copper bump formed by the use of a wire bonder. The size of the metal bump is ⅓to ⅔ of the size of the UBM structure, or ½ of the size of the UBM structure.

Further, another embodiment of a method for fabricating a conductive bump in the present invention comprises the steps of: providing a semiconductor device with a connection pad formed thereon, forming a passivation layer on the semiconductor device with the connection pad being exposed from the passivation layer, applying a metal layer and a resist layer in sequence over the semiconductor device, and forming an opening in the resist layer at a position corresponding to the connection pad for exposing a portion of the metal layer via the opening; forming at least one metal bump on the metal layer exposed via the opening of the resist layer, wherein the metal bump is sized smaller than the opening of the resist layer; forming a solder material in the opening of the resist layer by performing a plating process such that the metal bump is encapsulated by the solder material; removing the resist layer and a portion of the metal layer that is free of being covered by the solder material, so as to form an UBM structure on the connection pad; and performing a reflow process on the solder material to form a solder bump on the UBM structure, wherein the metal bump is completely encapsulated by the solder bump.

With the foregoing fabrication method, the invention also discloses a conductive bump structure for a semiconductor device. The conductive bump structure comprises: an UBM structure for electrically connecting to a connection pad of the semiconductor device; at least one metal bump formed on the UBM structure, wherein the metal bump is sized smaller than the UBM structure; and a solder bump formed on the UBM structure and completely encapsulating the metal bump.

Therefore, the conductive bump structure for the semiconductor device and the method for fabricating the same according to the present invention comprise: forming an UBM structure on the semiconductor device; covering the semiconductor device with a resist layer; forming an opening in the resist layer for exposing the UBM structure; forming a metal bump and a solder material in sequence on the UBM structure that is located in the opening of the resist layer and corresponding to the semiconductor device, wherein the metal bump is sized smaller than the UBM structure, so as to allow the solder material to completely encapsulate the metal bump for increasing bonding area of the solder material and to efficiently being wetted on the UBM structure. Accordingly, with the foregoing simple and low-cost fabricating processes, the present invention could strengthen the solder bump stress and the subsequent bonding strength generated when connecting the semiconductor device to external components via the solder bump, so as to avoid drawbacks of the prior art relating to the formation of IMC between gold and aluminum when mounting a gold bump directly on an aluminum pad for forming a solder bump, or the crack occurrence on the solder bump mounted on the gold bump due to the formation of IMC, as well as fulfilling the objectives, functions and technical solutions as aforementioned.

### BRIEF DESCRIPTION OF DRAWINGS

FIG. 1 (PRIOR ART) is a schematic cross-sectional view showing a semiconductor chip having an UBM structure and a solder bump in prior art;

FIGS. 2A to 2E (PRIOR ART) are schematic cross-sectional views showing procedural steps of a method for fabricating flip-chip solder bumps on a semiconductor wafer in prior art;

FIG. 3 (PRIOR ART) is a cross-sectional view showing procedural steps of a method for forming a gold bump and a solder material directly on an electrode connection pad of a chip disclosed in U.S. Pat. No. 5,633,204;

FIGS. 4A to 4E (PRIOR ART) are schematic cross-sectional views showing a conductive bump structure on an electrode connection pad of a wafer, which is fabricated by a method disclosed in U.S. Pat. No. 6,864,168;

FIGS. 5A to 5E are schematic cross-sectional views showing a method for fabricating a conductive bump structure for a semiconductor device according to a first embodiment of the present invention;

FIGS. 6A to 6F are schematic cross-sectional views showing a method of fabricating a conductive bump structure for a semiconductor device according to a second embodiment of the present invention;

FIG. 7 is a schematic cross-sectional view showing a conductive bump structure for a semiconductor device according to a third embodiment of the present invention; and

FIG. 8 is a schematic cross-sectional view of a conductive bump structure for a semiconductor device according to a fourth embodiment of the present invention.

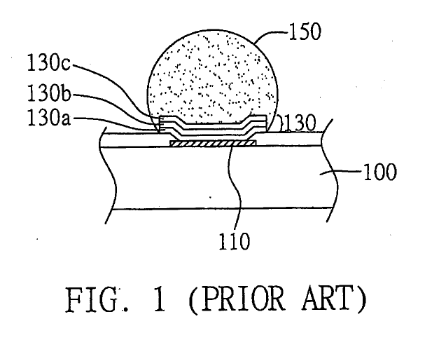

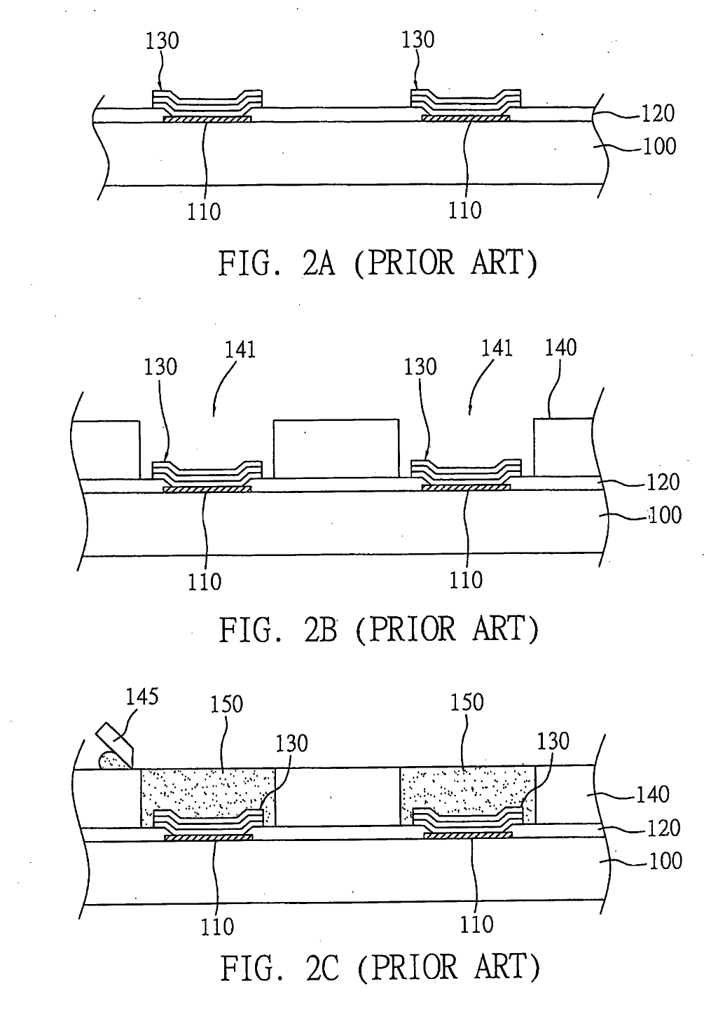

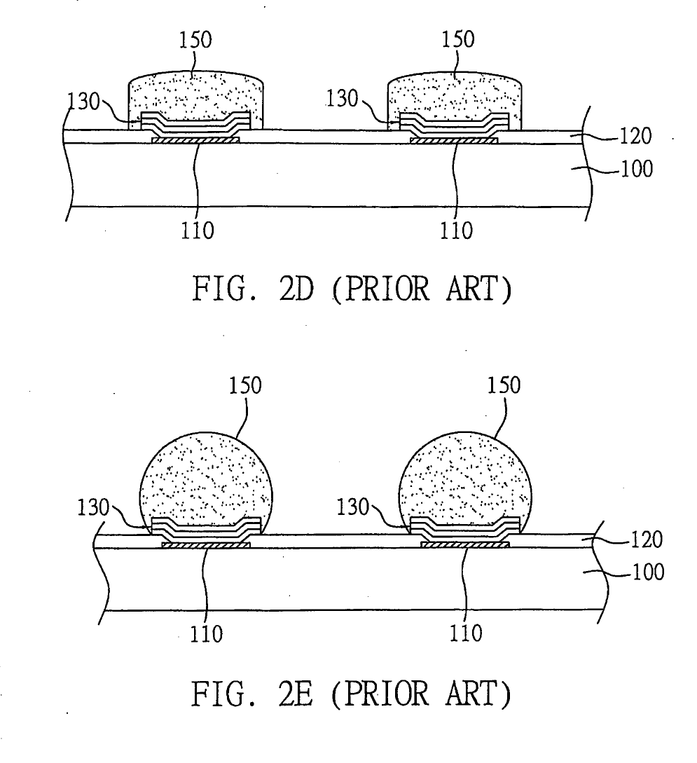

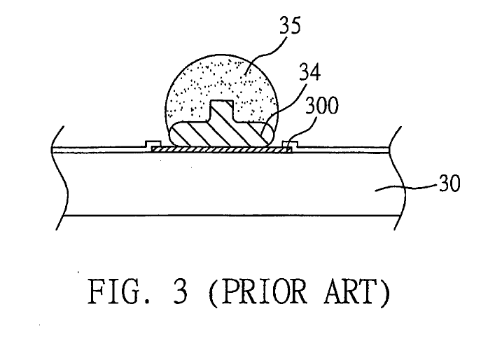

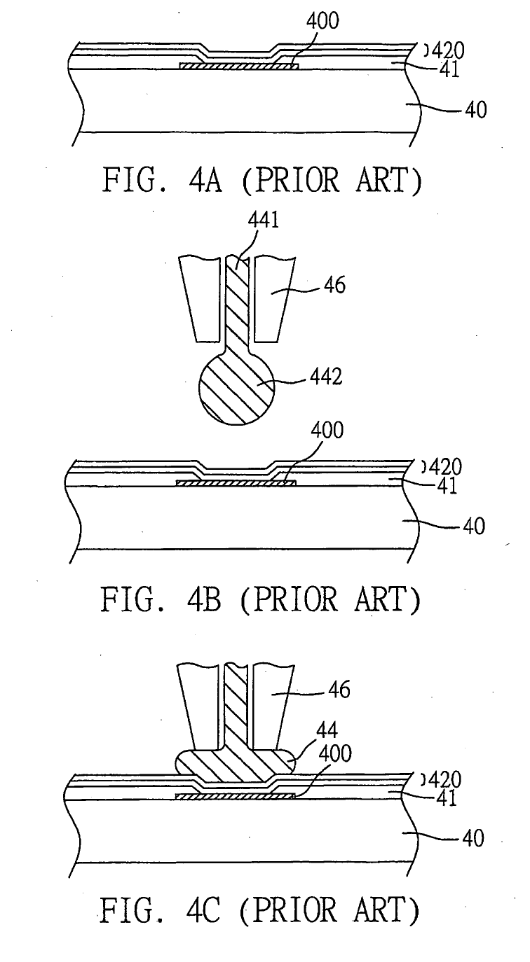

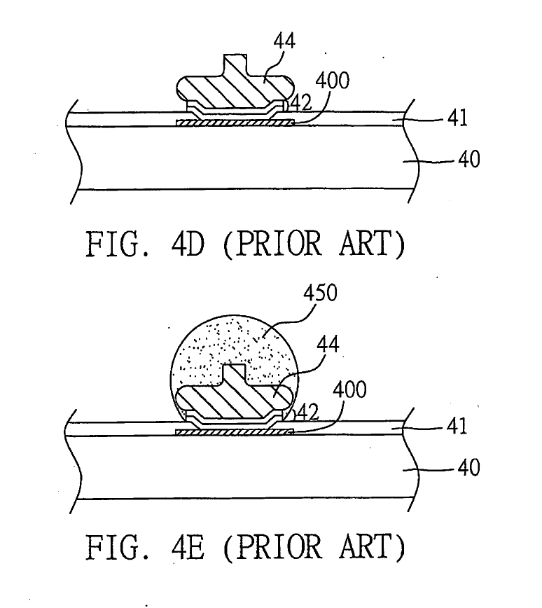

### DETAILED DESCRIPTION OF THE INVENTION

The following embodiments are described in sufficient detail to enable those skilled in the art to make and use the invention. It is to be understood that other embodiments would be evident based on the present disclosure, and that proves or mechanical changes may be made without departing from the scope of the present invention.

### First Preferred Embodiment

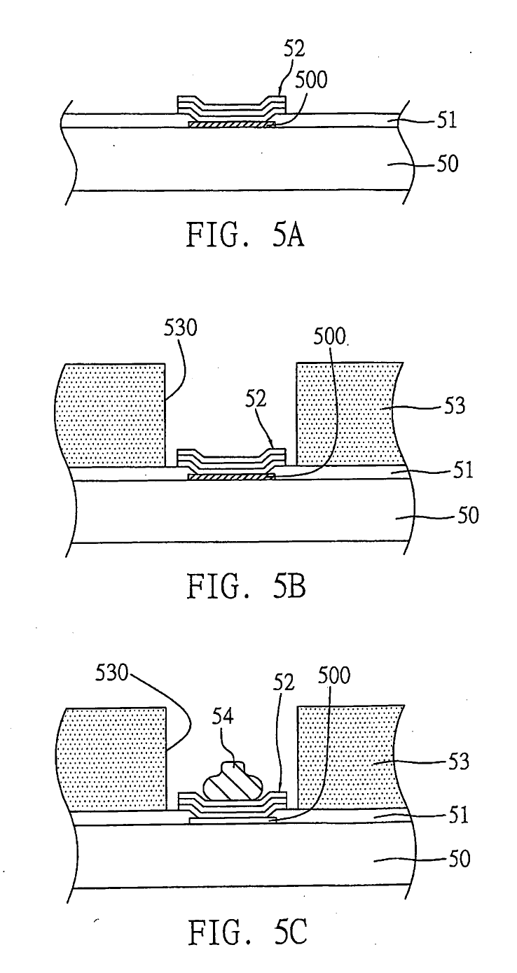

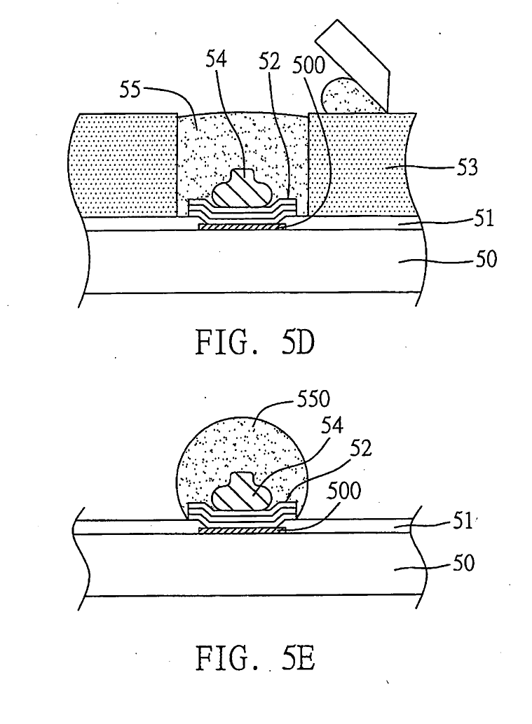

FIGS. 5A to 5E are schematic cross-sectional views showing a method for fabricating a conductive bump structure for a semiconductor device according to a first embodiment of the present invention.

As shown in FIG. 5A, a semiconductor device 50 with a connection pad 500 formed thereon is provided and a passivation layer 51 exposing the connection pad 500 is formed on the semiconductor device 50 such that an under bump metallurgy (UBM) structure 52 is formed on the connection pad 500 of the semiconductor device, wherein the UBM structure 52 is sized larger than the connection pad 500. The semiconductor device 50 may be used in a substrate for semiconductor package or a tape carrier such as a tape carrier package (TCP). The semiconductor device 50 may also be used in a printed circuit board for assembling electrical components in second phase. Furthermore, the semiconductor device may be used in a wafer/chip integrated circuit structure that may subsequently be used as a flip-chip semiconductor wafer/chip or wafer level chip scale package (WLCSP). The connection pad 500 is used as input/output for internal circuits of the semiconductor device 50 and may be redistributed through a redistribution layer (RDL). The passivation layer 51 is a dielectric layer made of at least one of a polyimide, silicon dioxide and silicon nitride in an ordinary fabricating process and employed for covering surface of the semiconductor device 50, so as to protect the semiconductor device 50 from pollutions or damages resulting from external environment. Further, the passivation layer 51 has a plurality of openings for exposing the connection pad 500, allowing the UBM structure 52 to be formed thereon. The connection pad 500 may be a copper layer or an aluminum layer.

The UBM structure 52 having one or more layers may mainly comprise at least one of an adhesion layer, a barrier layer and a wettable layer. Further, the UBM may be made by sputtering, evaporation or plating. If the UBM structure is applied to a flip-chip wafer/chip, the adhesion layer of the UBM structure may be made of titanium (Ti), aluminum (Al) or titanium-tungsten (TiW), the barrier layer of the UBM structure may be made of nickel (Ni) or nickel-vanadium (NiV) and the wettable layer of the UBM structure may be made of copper (Cu), gold (Au) or palladium (Pd) and the like. On the other hand, if the UBM structure is applied to a TCP structure, the UBM structure may be made of TiW/Au/Au.

As shown in FIG. 5B, a resist layer 53 such as a dry film is applied on the semiconductor device 50, and at least one opening 530 is subsequently formed in the resist layer 53 by performing processes such as exposing and developing on the resist layer 53 so as to expose the UBM structure 52.

As shown in FIG. 5C, at least one metal bump 54 is formed on the UBM structure 52, wherein the metal bump 54 is sized smaller than the UBM structure 52. The metal bump 54 may be ⅓ to ⅔ size of the UBM structure 52. Preferably, the metal bump 54 is ½ size of the UBM structure 52. Further, the metal bump is formed by using a wire bonder (not shown) to sinter at least a solder wire into a ball and pressing the ball onto the UBM structure, wherein the metal bump may be made of gold or copper. Although the accompanying drawings show only one metal bump, it is to be noted that the amount of the metal bump may vary in practice and should not be limited to that described and illustrated. If the size of the metal bump and the UBM structure are allowable, a plurality of metal bumps may be mounted on the UBM structure, so as to provide more bonding area for the solder bump that is subsequently mounted on the UBM structure.

As shown in FIG. 5D, a solder material 55 is formed in the opening 530 by printing process and the solder material 55 is fixed to the metal bump 54 and the UBM structure 52 by performing a first reflow process. The solder material 55 may be made of any ordinary tin-lead alloy such as 63/37 Sn/Pb alloy, a high lead alloys such as 90/10 or 95/5 Pb/Sn alloy, or a lead-free alloy such as 96.5/3/0.5 Sn/Ag/Cu alloy.

As shown in FIG. 5E, the resist layer 53 is removed and the solder material 55 is formed into a solder bump 550 by performing a second reflow process, such that the solder bump 550 could completely encapsulate the metal bump 54 to increase bonding area and be sufficiently wetted on the UBM structure 52 for enhancing bonding strength of the solder bump 550.

With the foregoing fabrication method, the invention also discloses a conductive bump structure for a semiconductor device. The conductive bump structure comprises: an UBM structure 52 for electrically connecting to a connection pad 500 of the semiconductor device; at least one metal bump 54 formed on the UBM structure 52, wherein the metal bump 54 is sized smaller than the UBM structure 52; and a solder bump 550 formed on the UBM structure 52 and completely encapsulating the metal bump 54.

Therefore, the conductive bump structure for the semiconductor device and the method for fabricating the same according to the present invention mainly comprise: forming an UBM structure on the semiconductor device; covering the semiconductor device with a resist layer; forming an opening in the resist layer for exposing the UBM structure; forming a metal bump and a solder material in sequence on the UBM structure that is located in the opening of the resist layer and corresponding to the semiconductor device, wherein the metal bump is sized smaller than the UBM structure, so as to allow the solder material to completely encapsulate the metal bump for increasing bonding area of the solder material and efficiently being wetted on the UBM structure. Accordingly, with the foregoing simple and low-cost fabricating processes, the present invention could strengthen the solder bump stress and the subsequent bonding strength generated when connecting the semiconductor device to external components via the solder bump, so as to avoid drawbacks of the prior art relating to the formation of IMC between gold and aluminum when mounting a gold bump directly on an aluminum pad for forming a solder bump, or the crack occurrence on the solder bump mounted on the gold bump due to the formation of IMC, as well as avoiding increase in cost of production and process complexity resulting from the use of copper pillar. As a result, the metal bump would be relatively sized smaller than the UBM structure that is relatively sized larger than the connection pad, so that the stress of the whole solder bump subsequently formed on the connection pad is not limited, allowing the stress and location of the solder bump not to be affected by unfavorable or adverse influences on the precision of the metal bump and the wire bonder. Further, the design of the present invention also allows the solder bump to be efficiently wetted on the UBM structure for strengthen the solder bump, so as to further increase the bonding strength between the semiconductor device and external components as well as to prolong the life time of the solder junction used for electrically connecting the semiconductor device to external components.

### Second Preferred Embodiment

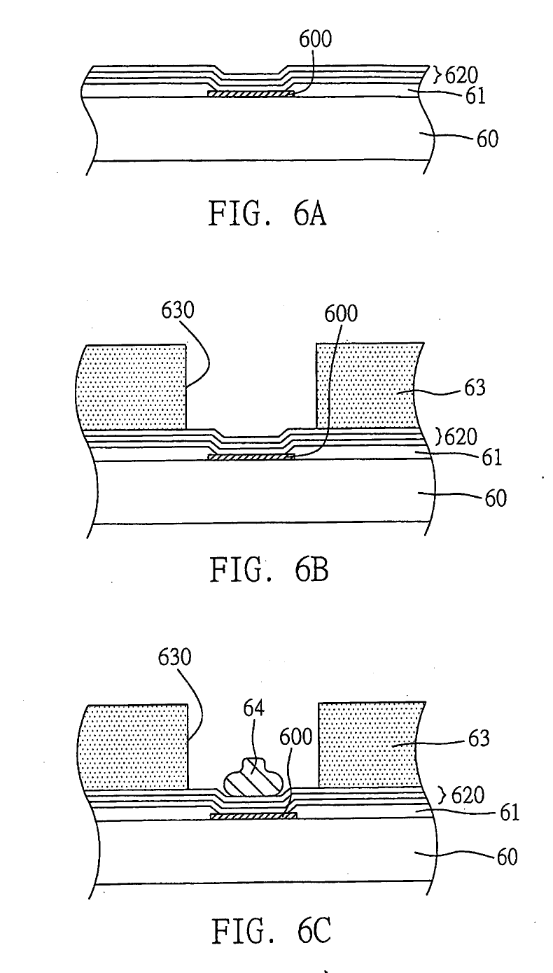

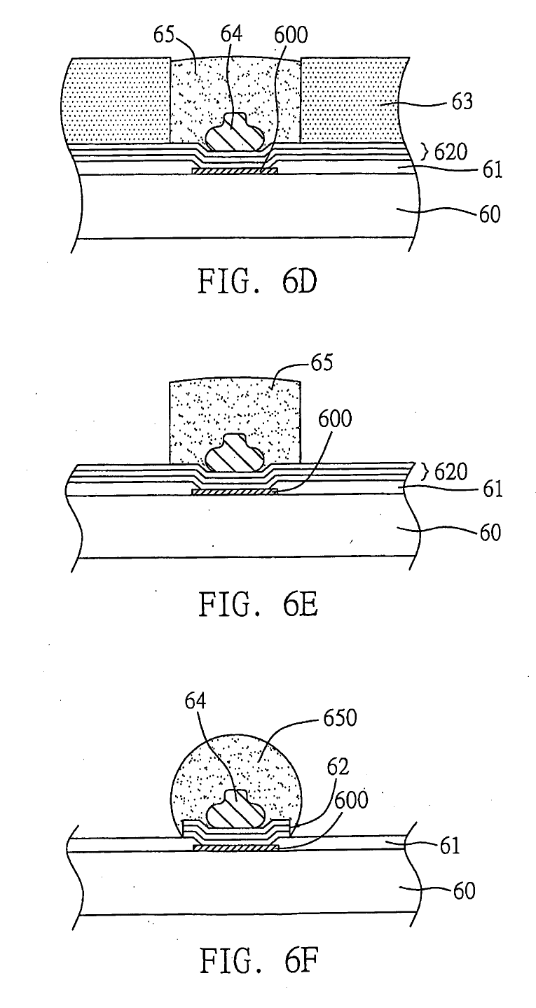

FIGS. 6A to 6F are schematic cross-sectional views showing a method of fabricating a conductive bump structure for a semiconductor device according to a second embodiment of the present invention.

As shown in FIGS. 6A and 6B, a semiconductor device 60 with a connection pad 600 formed thereon is provided and a passivation layer 61 exposing the connection pad 600 is formed on the semiconductor device 60. Thereafter a metal layer 620 and a resist layer 63 are applied in sequence over the semiconductor device 60, wherein the resist layer 63 has an opening 630 corresponding to the connection pad 600 for exposing a portion of the metal layer 620. The metal layer 620 may have one or more layers and be used as a current conduction path during plating process for forming solder, as well as reserving a portion of metal layer 620 at a position corresponding to the connection pad 600 for subsequently forming an UBM structure. The metal layer 620 may be formed by physical methods such as sputtering, evaporation or plating, or chemical methods such as chemical deposition.

As shown in FIG. 6C, at least one metal bump 64 is formed on the exposed metal layer 620 in the opening 630. The size of the metal bump 64 is relatively smaller than that of the opening 630, wherein the metal bump 64 may be ⅓ to ⅔ size of the opening 630. Preferably, the metal bump 64 is ½ size of the opening 630. Further, the metal bump is formed by the use of a wire bonder (not shown) to sinter a wire into a ball and pressing the ball onto the UBM structure, wherein the metal bump may be made of gold or copper. Although the accompanying drawings show only one metal bump, it should be understood that the amount of the metal bump may vary in practice and should not be limited to that described and illustrated. If the size of the metal bump and the opening are allowable, a plurality of metal bumps may be mounted on the metal layer.

As shown in FIG. 6D, a solder material 65 is formed in the opening 630 by plating, such that the solder material 65 encapsulates the metal bump 64.

As shown in FIG. 6E, the resist layer 63 is removed by etching or any other method having similar effect.

As shown in FIG. 6F, the solder material 65 is used as an etching resist layer to remove a portion of the metal layer 620 that is not covered by the solder material 65 by etching, so as to form an UBM structure 62 on the connection pad 600. Furthermore, the solder material 65 is formed into a solder bump 650 by performing a reflow process, such that the solder bump 650 could completely encapsulate the metal bump 64 to increase bonding area and be sufficiently wetted on the UBM structure 62 for enhancing bonding strength of the solder bump 650.

### Third Preferred Embodiment

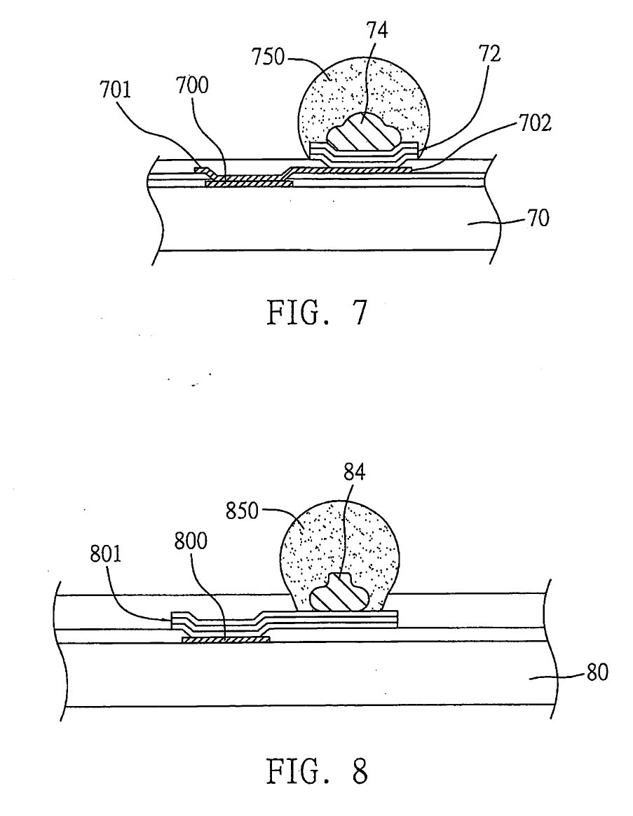

FIG. 7 is a schematic cross-sectional view showing a conductive bump structure for a semiconductor device according to a third embodiment of the present invention.

The method of fabricating the conductive bump structure for semiconductor device in the present embodiment is similar to the method disclosed in the first or the second embodiment; however the differences are that the present embodiment comprises a conductive bump structure that is applied to a wafer level chip scale package (WLCSP) structure, and a redistribution layer 701 (RDL) electrically connecting to and formed on at least a connection pad 700 of a chip 70, wherein the existing connection pad 700 may be redistributed through the redistribution layer 701 electrically connected to the connection pad 700. Subsequently, an UBM structure 72 and a metal bump 74 are formed on a suitable position on the redistribution layer 701 that serves as a new connection pad 702, wherein the metal bump 74 is sized smaller than the UBM structure 72, such that a solder bump 750 subsequently mounted to the UBM structure 72 by printing or plating could encapsulate the metal bump 74 to increase bonding area and simultaneously be sufficiently wetted on the UBM structure 72 for enhancing bonding strength of the solder bump.

The redistribution layer 701 may be made of Ti/NiV/Cu; the UBM structure 72 may be made of TiW/Au/Au or Ni/Au; and the metal bump 74 may be made of copper or gold.

### Fourth Preferred Embodiment

FIG. 8 is a schematic cross-sectional view of a conductive bump structure for a semiconductor device according to a fourth embodiment of the present invention. The method of fabricating a conductive bump structure for a semiconductor device in the present embodiment is similar to the first embodiment; however the differences are that the present embodiment comprises a conductive bump structure that is applied to a wafer level chip scale package (WLCSP) structure, and a redistribution layer 801 (RDL) electrically connected to and formed on at least a connection pad 800 of a chip 80, wherein the existing connection pad 800 may be redistributed through the redistribution layer 801, which has an end thereof serving as the UBM structure allowing a metal bump 84 and a solder bump 850 to be mounted thereon. The metal bump 84 is sized smaller than the UBM structure, such that a solder bump 850 subsequently mounted to the UBM structure could encapsulate the metal bump 84 to increase bonding area and simultaneously be sufficiently wetted on the UBM structure for enhancing bonding strength of the solder bump.

The redistribution layer 801 may be made of TiW/Au/Au; and the metal bump 84 may be made of copper or gold.

The invention has been described using exemplary preferred embodiments. However, it is to be understood that the scope of the invention is not limited to the disclosed embodiments. On the contrary, it is intended to cover various modifications and similar arrangement. The scope of the claims therefore should be accorded the broadest interpretation so as to encompass all such modifications and similar arrangements.

What is claimed is:

1. A method for fabricating a conductive bump structure for a semiconductor device, comprising the steps of:
providing the semiconductor device with a connection pad formed thereon and forming an under bump metallurgy (UBM) structure on the connection pad of the semiconductor device, wherein the UBM structure is electrically connected to the connection pad;
applying a resist layer on the semiconductor device, and forming an opening in the resist layer for exposing the UBM structure via the opening;
forming at least one metal bump on the UBM structure, wherein the metal bump is sized smaller than the UBM structure;
forming a solder material in the opening by printing, and performing a first reflow process for fixing the solder material to the metal bump and the UBM structure; and
removing the resist layer, and performing a second reflow process for forming a solder bump on the UBM structure, wherein the solder bump completely encapsulates the metal bump.

2. The method of claim 1, wherein the semiconductor device is at least one of a semiconductor chip, a wafer, a semiconductor package substrate, a tape carrier and a circuit board.

3. The method of claim 1, wherein the semiconductor device subsequently serves as at least one of a flip-chip semiconductor wafer/chip and a wafer level chip scale package structure.

4. The method of claim 1, wherein the UBM structure is sized larger than the connection pad of the semiconductor device.

5. The method of claim 1, wherein the connection pad is redistributed through a redistribution layer electrically connected to the connection pad, such that the UBM structure is formed on a suitable position on the redistributed layer.

6. The method of claim 5, wherein the redistribution layer comprises Ti/NiV/Cu and the UBM structure comprises a material selected from the group consisting of TiW/Au/Au and Ni/Au.

7. The method of claim 1, wherein the connection pad is redistributed through a redistribution layer electrically connected to the connection pad, and the redistribution layer has an end thereof serving as the UBM structure with the metal bump and the solder bump being formed thereon.

8. The method of claim 7, wherein the redistribution layer comprises TiW/Au/Au.

9. The method of claim 1, wherein the UBM structure comprises one or more layers comprising at least one of an adhesion layer, a barrier layer and a wettable layer.

10. The method of claim 9, wherein the adhesion layer of the UBM structure comprises a material selected from the group consisting of titanium (Ti), aluminum (Al) and titanium-tungsten (TiW), the barrier layer of the UBM structure comprises a material selected from the group consisting of nickel (Ni) and nickel-vanadium (NiV), and the wettable layer of the UBM structure comprises a material selected from the group consisting of copper (Cu), gold (Au) and palladium (Pd).

11. The method of claim 1, wherein the UBM structure comprises TiW/Au/Au.

12. The method of claim 1, wherein the metal bump is formed by the use of a wire bonder to sinter a wire into a ball and press the ball onto the UBM structure.

13. The method of claim 1, wherein the metal bump comprises a material selected from the group consisting of gold (Au) and copper (Cu).

14. The method of claim 1, wherein the size of the metal bump is one-third to two-third of the size of the UBM structure, and preferably, the size of the metal bump is half of the size of the UBM structure.

15. A method for fabricating a conductive bump structure for a semiconductor device, comprising the steps of:
providing the semiconductor device with a connection pad formed thereon, forming a passivation layer on the semiconductor device with the connection pad being exposed from the passivation layer, applying a metal layer and a resist layer in sequence over the semiconductor device, and forming an opening in the resist layer at a position corresponding to the connection pad for exposing a portion of the metal layer via the opening;
forming at least one metal bump on the metal layer exposed via the opening of the resist layer, wherein the metal bump is sized smaller than the opening of the resist layer;
forming a solder material in the opening of the resist layer by performing a plating process such that the metal bump is encapsulated by the solder material;
removing the resist layer and a portion of the metal layer that is free of being covered by the solder material, so as to form an UBM structure on the connection pad; and
performing a reflow process on the solder material to form a solder bump on the UBM structure, wherein the metal bump is completely encapsulated by the solder bump.

16. The method of claim 15, wherein the semiconductor device is at least one of a semiconductor chip, a wafer, a semiconductor package substrate, a tape carrier and a circuit board.

17. The method of claim 15, wherein the semiconductor device is subsequently served as at least one of a flip-chip semiconductor wafer/chip and a wafer level chip scale package structure.

18. The method of claim 15, wherein the UBM structure is sized larger than the connection pad of the semiconductor device.

19. The method of claim 15, wherein the connection pad is redistributed through a redistribution layer electrically connected to the connection pad, such that the UBM structure is formed on a suitable position on the redistributed layer.

20. The method of claim 19, wherein the redistribution layer comprises Ti/NiV/Cu and the UBM structure comprises a material selected from the group consisting of TiW/Au/Au and Ni/Au.

21. The method of claim 15, wherein the UBM structure comprises one or more layers comprising at least one of an adhesion layer, a barrier layer and a wettable layer.

22. The method of claim 21, wherein the adhesion layer of the UBM structure comprises a material selected from the group consisting of titanium (Ti), aluminum (Al) and titanium-tungsten (TiW), the barrier layer of the UBM structure comprises a material selected from the group consisting of nickel (Ni) and nickel-vanadium (NiV); the wettable layer of the UBM structure comprises a material selected from the group consisting of copper (Cu), gold (Au) and palladium (Pd).

23. The method of claim 15, wherein the UBM structure comprises TiW/Au/Au.

24. The method of claim 15, wherein the metal bump is formed by the use of a wire bonder to sinter a wire into a ball and press the ball onto the UBM structure.

25. The method of claim 15, wherein the metal bump comprises a material selected from the group consisting of gold (Au) and copper (Cu).

26. The method of claim 15, wherein the metal bump is one-third to two-third of the size of the UBM structure, and preferably, the size of the metal bump is half of the size of the UBM structure.

27. A conductive bump structure for a semiconductor device, comprising:
an UBM structure formed on the semiconductor device and electrically connected to a connection pad of the semiconductor device;
at least one metal bump formed on the UBM structure, wherein the metal bump is sized smaller than the UBM structure; and
a solder bump formed on the UBM structure, wherein the solder bump completely encapsulates the metal bump.

28. The conductive bump structure of claim 27, wherein the semiconductor device is at least one of a semiconductor chip, a wafer, a semiconductor package substrate, a tape carrier, and a circuit board.

29. The conductive bump structure of claim 27, wherein the semiconductor device subsequently serves as at least one of a flip-chip semiconductor wafer/chip and a wafer level chip scale package structure.

30. The conductive bump structure of claim 27, wherein the UBM structure is sized larger than the connection pad of the semiconductor device.

31. The conductive bump structure of claim 27, wherein the connection pad is redistributed through a redistribution layer electrically connected to the connection pad, such that the UBM structure is formed on a suitable position on the redistribution layer.

32. The conductive bump structure of claim 31, wherein the redistribution layer comprises Ti/NiV/Cu and the UBM structure comprises a material selected from the group consisting of TiW/Au/Au and Ni/Au.

33. The conductive bump structure of claim 27, wherein the connection pad is redistributed through a redistribution layer electrically connected to the connection pad, and the redistribution layer has an end thereof serving as the UBM structure with the metal bump and the solder bump being formed thereon.

34. The conductive bump structure of claim 33, wherein the redistribution layer comprises TiW/Au/Au.

35. The conductive bump structure of claim 27, wherein the UBM structure comprises one or more layers comprising at least one of an adhesion layer, a barrier layer and a wettable layer.

36. The conductive bump structure of claim 35, wherein the adhesion layer of the UBM structure comprises a material selected from the group consisting of titanium (Ti), aluminum (Al) and titanium-tungsten (TiW), the barrier layer of the UBM structure comprises a material selected from the group consisting of nickel (Ni) and nickel-vanadium (NiV), and the wettable layer of the UBM structure comprises a material selected from the group consisting of copper (Cu), gold (Au) and palladium (Pd).

37. The conductive bump structure of claim 27, wherein the UBM structure comprises TiW/Au/Au.

38. The conductive bump structure of claim 27, wherein the metal bump is formed by the use of a wire bonder to sinter a wire into a ball and press the ball onto the UBM structure.

39. The conductive bump structure of claim 27, wherein the metal bump comprises a material selected from the group consisting of gold (Au) and copper (Cu).

40. The conductive bump structure of claim 27, wherein the size of the metal bump is one-third to two-third of the size of the UBM structure, and preferably, the size of the metal bump is half of the size of the UBM structure.
